(19) United States
(12) Patent Application Publication
(10) Pub. No.: US 2009/0047748 A1
(43) Pub. Date: Feb. 19, 2009

(54) ENHANCED SENSITIVITY NON-CONTACT ELECTRICAL MONITORING OF COPPER CONTAMINATION ON SILICON SURFACE

(76) Inventors: Alexandre Savtchouk, Tampa, FL (US); Jacek Lagowski, Tampa, FL (US); Lubomir L. Jastrzebski, Clearwater, FL (US); Joseph Nicholas Kochey, St. Petersburg, FL (US)

Correspondence Address: FISH & RICHARDSON P.C., P.O. BOX 1022, MINNEAPOLIS, MN, 55440-1022, US

(21) Appl. No.: 12/130,711

(22) Filed: May 30, 2008

Related U.S. Application Data
(60) Provisional application No. 60/942,353, filed on Jun. 6, 2007.

(51) Int. Cl. H01L 21/66

(52) U.S. Cl. 438/17; 257/E21.531

(57) ABSTRACT

Methods of measuring copper impurities on a silicon surface are disclosed. In certain embodiments, copper is electrically activated by ultra-violet illumination of the surface at room temperature. Activation can enhance the copper contribution to surface recombination and to surface voltage which are measured in a non-contact manner using a ac-surface photovoltage and a vibrating Kelvin-probe, respectively. Differential measurements before and after activation enable the separations of the copper impurities from other surface contaminants.

### CROSS-REFERENCE TO RELATED APPLICATIONS

This application claims priority to Provisional Patent Application No. 60/942,353, filed on Jun. 6, 2007, the entire contents of which are incorporated herein by reference.

### BACKGROUND

Monitoring of copper contamination of silicon wafers has recently become increasingly important for ultra large scale (LS) integrated circuit (IC) manufacturing due to the adoption of copper as an interconnect material.

To increase speed and reduce heat dissipation, IC manufacturers have replaced aluminum (Al) interconnects with copper (Cu) interconnects. The Cu interconnect fabrication process typically involves a large number of steps during which cross-contamination of the silicon wafer by Cu can take place. Especially vulnerable are the edges, the bevel, and the backside of Si wafers, where exposed Si surfaces could meet Cu containing solutions, vapors, slurries and electroplated film residues. Due to the high solubility and diffusivity of Cu at low temperatures (e.g., up to 400° C.) used during back-end processing, this Cu contamination can diffuse into the Si wafer and spread over a distance of, e.g., a few mm. If Cu reaches the active device area, it can degrade the gate dielectric resulting in reliability and yield issues. Some of the yield issues with circuits close to the wafer edge are attributed to Cu edge contamination.

### SUMMARY

The inventors have discovered techniques for enhancing sensitivity of non-contact electrical monitoring of copper (Cu) contamination on silicon (Si) surfaces. Accordingly, methods and systems that utilize these techniques for monitoring Cu contamination are disclosed.

In general, in one aspect, the invention features a method that includes exposing a silicon wafer to a dose of radiation having wavelength, λ_{A}, measuring an electrical parameter of the silicon wafer after exposing the silicon wafer to the radiation, and determining and outputting information about copper contamination of the silicon wafer based on the measured electrical parameter. The dose provides sufficient energy at λ_{A} to substantially activate copper contaminating the silicon wafer. λ_{A} can be about 450 nm or less (e.g., about 400 nm or less, about 350 nm or less, about, 320 nm or less, about 300 nm or less, about 250 nm or less, about 200 nm or less).

In general, in another aspect, the invention features a method that includes exposing a silicon (Si) wafer to a dose of ultra-violet (UV) radiation, wherein the conditions of illumination are sufficient to substantially enhance electrical activity of Cu contaminating the Si wafer, measuring an electrical parameter of the Si wafer after the exposure, and determining and outputting information about Cu contamination of the silicon wafer surface based on a measured variance of the electrical parameter before and after activation.

Embodiments of the methods can include one or more of the following features. For example, the information about copper contamination can be determined based on a value of the surface electrical parameters of the silicon wafer measured after activation of Cu by exposing the wafer to UV radiation. In some embodiments, the electrical parameter is a surface lifetime, τ_{S}, measured by alternating current (a.c.) surface photovoltage and surface Cu concentration N_{Cu} is determined from the difference of Δ(1/τ_{S}) before and after UV Cu activation. The electrical parameter can be a low frequency saturation surface photovoltage, V_{SPV0} and surface Cu concentration can be determined from the difference Δ(1/V_{SPV0}) before and after UV Cu activation. The electrical parameter can be a surface voltage, V_{CPD} measured by contact potential difference technique CPD and the information about the Cu contamination (e.g., concentration) can be determined from the difference of surface voltage measured before and after UV Cu activation. The electrical parameter can be a semiconductor surface barrier, V_{SB}, measured as the difference of V_{CPD} in the dark and under illumination and the information about the Cu contamination (e.g., concentration) can be determined from the difference ΔV_{SB} before and after UV Cu activation. The surface barrier V_{SB} can also be measured by high frequency ac-SPV.

In some embodiments, the electrical parameter is measured at a bevel of the silicon wafer. Alternatively, or additionally, the electrical parameter can be measured at a top surface of the silicon wafer. Alternatively, or additionally, the electrical parameter can be measured at a bottom surface of the silicon wafer.

The electrical parameter can be measured using a non-contact probe (e.g., a vibrating non-contact probe), such as a Kelvin probe.

The ultra-violet radiation dose can correspond to a dose provided by a UVO-cleaner® manufactured by Jelight Company, Inc. (e.g., including a Suprasil® UV quartz lamp), for time of about 10 seconds or more (e.g., 20 seconds or more, 30 seconds or more, 60 seconds or more, 2 minutes or more, 5 minutes or more).

The light source can be broadband or narrowband (e.g., monochromatic).

The wafer can be at room temperature during the exposure and measurement.

Among other advantages, the inventive techniques can provide copper contamination methods that are both quantitative and selective. Moreover, the techniques are extremely sensitive, providing measurements of copper surface contamination in the range of 10¹² atoms/cm² or less (e.g., 10¹¹ atoms/cm² or less, 10¹⁰ atoms/cm² or less, 10⁹ atoms/cm² or less).

### BRIEF DESCRIPTION OF DRAWINGS

FIG. 1 is a schematic diagram of an embodiment of a tool for determining information about copper contamination of a silicon wafer.

FIG. 2A is a schematic diagram showing different configurations for a radiation source in a tool for determining information about copper contamination of a silicon wafer.

FIG. 2B is a schematic diagram of a mount for positioning a wafer within a tool for determining information about copper contamination of a silicon wafer.

FIGS. 3A-3D are plots of measured electric properties of a surface of a 10Ω cm p-type Si without intentional Cu contamination—reference; and with Cu contamination by 10 min. soaking in buffered HF with 5 ppb of Cu. The reference wafer was soaked in buffered HF with no addition of Cu. FIG. 3A shows measured V_{CPD}; FIG. 3B shows measured V_{SPV}(0); FIG. 3C shows measured V_{SB}; and FIG. 3D shows measured τ_{S}.

FIGS. 4A-4C are plots of a ratio X_{reference}/X_{contaminated}, where X is τ_{S}, V_{SPV}(0), and V_{SB}, respectively, before and after Cu activation. These plots illustrate the sensitivity of the techniques to Cu contamination. Note that for parameters measured with ac-SPV, i.e., τ_{S} and V_{SPV0}, the activation increases the ratio by about 60 times.

FIG. 5 is a plot illustrating a process for calculating surface copper concentration N_{Cu} from the measurement of the surface lifetime, τ_{S} before and after UV optical activation. In this case, the illumination was provided by a 5 min exposure of the wafer surface at room temperature in a UVO-cleaner, obtained from Jelight Company, Inc. Note linear dependence of Δ(1/τ_{S}) on N_{Cu} determined by the analytical technique TXRF. Calibration constant 1.5e11 in N_{Cu} equation was determined from data shown in figure.

### DETAILED DESCRIPTION

Copper (Cu) on a silicon (Si) wafer surface can increase surface recombination and can change the surface charge on the wafer. These two electrical manifestations provide a basis for measuring information about the copper concentration, N_{Cu}, on a surface of a Si wafer with non-contact methods sensitive to surface recombination, such as ac-surface photovoltage or photoconductive decay method, or a vibrating Kelvin probe that measures the surface voltage and surface barrier sensitive to the surface charge.

It is believed that these approaches can be limited by the fact that typically only a small fraction of copper impurities, e.g., of about 0.3%, are in an electrically active state on the silicon surface. In general, the vast majority of surface Cu is electrically inactive, and thus invisible in electrical measurements. In other words, a very small fraction of copper contaminants typically provide surface recombination centers or charge trapping centers. Moreover, even in the electrically active state, it can be difficult to distinguish Cu from other electrically active species. This can limit Cu detection sensitivity, especially at low concentrations, making it difficult to measure Cu in the 10¹⁰ atoms/cm² range and below which is often desired for IC process monitoring.

Accordingly, methods of determining information about relatively low concentration copper contamination of silicon wafers are disclosed. In general, the methods involve electrically activating copper contaminants on the silicon surface and measuring an electrical parameter (P) of the silicon before (P₁) and after (P₂) activation. A variation in the measurement parameter (e.g., ΔP=P₂-P_{P}₁ or Δ1/P=1/P₂-1/P₁) between measurements made before and after activation provides information about the Cu contamination and serves to determine N_{Cu}. Subsequently, information about the copper contaminants is output as desired (e.g., displayed to a process engineer or used in a feedback or feedforward manner in a manufacturing process).

In general, copper activation is performed by exposing the wafer to a suitable dose of blue and/or ultra-violet radiation of an appropriate wavelength (e.g., radiation at a wavelength of about 400 nm or less, 380 nm or less, about 350 nm or less, about 300 nm or less, about 250 nm or less, about 200 nm or less). It is believed that the short wavelength radiation interacts with surface species on the wafer without causing noticeable changes in the bulk of the silicon wafer. Appropriate wavelengths include UV wavelengths from a mercury lamp or other broadband UV emitter. A suitable dose results in substantial activation of the copper electrical surface activity, i.e., that causes a significant change in a measured electrical parameter (e.g., by a factor of 3 or more, 5 or more, 10 or more, 20 or more, 50 or more, 100 or more, depending on the electrical parameter.

Electrical parameters which can manifest enhanced readings due to copper activation include, for example, the surface lifetime, τ_{S}, the low frequency saturation ac-surface photovoltage (SPV), V_{SPV0}, the surface voltage, V_{CPD}, and the semiconductor surface barrier, V_{SB} or surface recombination. Techniques for measuring τ_{S} are disclosed, for example, in M. Wilson, A. Savtchouk, J. D'Amico, I. Tarasov, L. Jastrzebski, and J. Lagowski, “MANIFESTATION OF CU IMPURITIES ON SILICON SURFACES, IMPLICATION FOR MONITORING CU CONTAMINATION,” published at ECS Transactions, 11 (3) 347-361 (2007) the entire contents of which are incorporated herein by reference. Techniques for measuring surface photovoltage are disclosed, for example, in U.S. Pat. No. 6,512,384, entitled “METHOD FOR FAST AND ACCURATE DETERMINATION OF THE MINORITY CARRIER DIFFUSION LENGTH FROM SIMULTANEOUSLY MEASURED SURFACE PHOTOVOLTAGES,” the entire contents of which are incorporated herein by reference. Techniques for measuring V_{CPD} are disclosed, for example, by J. Lagowski and P. Edelman in “CONTACT POTENTIAL DIFFERENCE METHODS FOR FULL WAFER CHARACTERIZATION OF OXIDIZED SILICON,” Inst. Phys. Conf., Ser. No. 160, p. 133-144 (1997), and by D. K. Schroder in “CONTACTLESS SURFACE CHARGE SEMICONDUCTOR CHARACTERIZATION,” Material Science and Engineering, B91-92, p. 196-210 (2002), the entire contents both of which are incorporated herein by reference. Techniques for measuring V_{SB} are disclosed, for example, in U.S. Pat. No. 6,037,797, entitled “MEASUREMENT OF THE INTERFACE TRAP CHARGE IN AN OXIDE SEMICONDUCTOR LAYER INTERFACE,” the entire contents of which are incorporated herein by reference.

A suitable dose of radiation can change a measured value of τ_{S} by about 10 times or more (e.g., about 20 times or more, about 50 times or more). A suitable dose of radiation can change a measured value of V_{SPV0} by about 10 times or more (e.g., about 20 times or more, about 50 times or more, about 80 times or more). A suitable dose of radiation can change a measured value of V_{CPD} by about 5 times or more (e.g., about 10 times or more). A suitable dose of radiation can change a measured value of V_{SB} by about 5 times or more (e.g., about 10 times or more).

Measurements of the electrical parameter can be performed using a non contact probe, such as a vibrating Kelvin probe for V_{CPD} or V_{SB} and a stationary transparent SPV probe for ac-SPV measurements that provide τ_{S} and V_{SPV0}. In some embodiments, surface properties ac-SPV measurements are performed by using modulated light (e.g., pulsed light or sinusoidally modulated light) with short penetration depth beneath the Si surface. For example, a blue LED light with the wavelength of 470 nm and penetration depth into Si of about 0.6 μm can be used.

In general, activation and/or measurements before and after activation can be performed at a variety of temperatures. In some embodiments, activation and/or measurements are performed at the room temperature (e.g., 21° C.±0.1° C.).

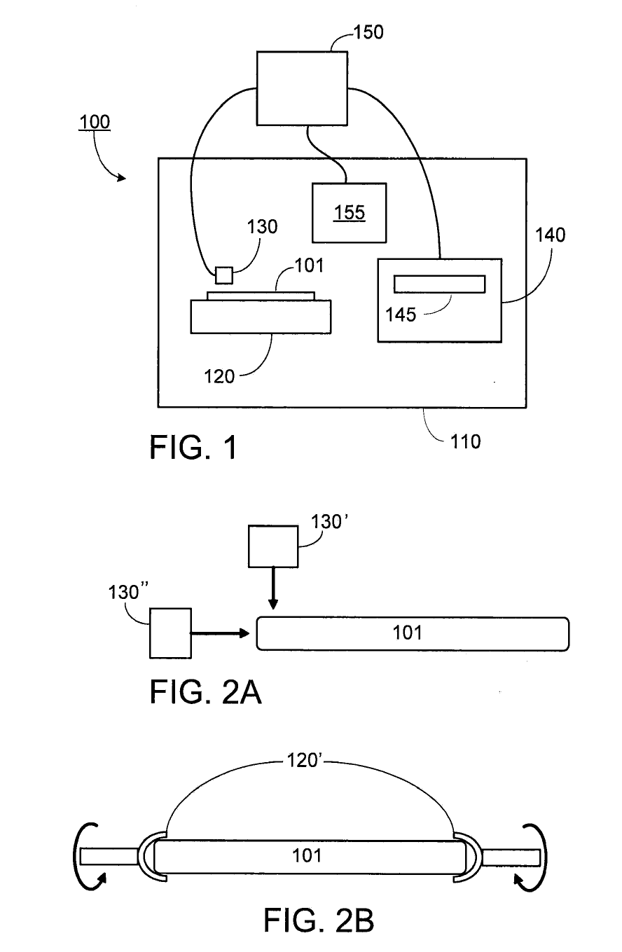

Referring to FIG. 1, an embodiment of a measurement tool 100 for measuring copper contamination in a wafer 101 includes a housing 110, a mount 120, a probe 130 for measuring a copper sensitive parameter P, an activation station 140 including a light source 145, and an electronic controller 150. Mount 120 positions wafer 101 relative to probe 130. Tool 100 also includes a wafer handling subsystem 155 (e.g., including a robotic arm), which transfers wafer 101 between mount 120 and activation station 140. Electronic controller 150 is in communication with activation station 140, probe 130, and wafer handling subsystem 155, and co-ordinates illumination of the wafer by activation station 140 and detection of an electrical property of the wafer using probe 130.

In general, the location of probe 130 with respect to wafer 101 can vary as desired. Typically, probe 130 and mount 120 are arranged to position the portion of wafer 101 to be measured in sufficiently close proximity to probe 130. FIG. 2A illustrates exemplary arrangements of probe 130 with respect to wafer 101. For example, measurement tool 100 can be arranged with light source 130′ configured to measure the front surface (i.e., patterned surface) or back surface of wafer 101, close to the edge and/or nearer the center. Alternatively, or additionally, measurement tool 100 can be arranged with probe 130″ configured to measure the edge of wafer 101.

In general, a variety of mounting configurations can be used. For example, mount 120 can be a stage that supports wafer 101 within tool 100. In some embodiments, as shown in FIG. 2B, mount 120′ can include edge grippers that clamp to the edge of the wafer at one or more locations and hold wafer 101 within tool 100. Edge grippers can be advantageous in that they result in reduced contact of the front or back surface of wafer 101 with tool 100, reducing additional contamination of the front or back wafer surfaces due to contaminants present in the tool. In some embodiments, mount 120′ can include a mechanism to flip the wafer, providing ability to position the front or back wafer surface for measurement.

In some embodiments, probe 130 can be scanned relative to wafer 101 and measurements can be acquired for multiple different locations of the wafer surface. The multiple measurements can be used to determine a copper contamination distribution across the wafer surface (e.g., a map, such as a contour map, illustrating areas of high or low contamination). Alternatively, or additionally, probe 130 can be stationary and wafer 101 can be scanned relative to probe 130 (e.g., via wafer handling system 155).

Without wishing to be bound by theory, it is believed that the activation transfers surface Cu from an inactive to an electrically active state at the Si surface or Si-native oxide interface. For ac-SPV measurement this active state means the electron-hole surface recombination center that reduces the surface lifetime, τ_{S}, in a way such that the change in 1/τ_{S} before and after activation, Δ1/τ_{S}, becomes approximately proportional to N_{Cu}. The proportionality constant quantitatively relating N_{Cu} to Δ1/τ_{S} can be determined, for example, using Total reflection X-ray Fluorescence (TXRF) measurements in a calibration procedure.

For surface barrier voltage measurements, the active state means negatively charged centers lower the V_{SB} in p-type silicon and correspondingly change V_{CPD}. As a result, this method can give significant enhancement of sensitivity to measurements of these electrical parameters, and can be capable of meeting detection sensitivities of less than about 10¹⁰ atoms/cm², desired for advanced Si microelectronics. The selective character of activation and differential measurement serves to distinguish the Cu contribution from other electrically active species.

As discussed previously, the electrical monitoring of copper is applicable to the front (the surface where the IC is formed) and back surfaces of the silicon wafer, to the wafer surface near the edge and the wafer bevel. The latter can be achieved using appropriate configuration of small area probes facing the wafer edge, e.g., for both ac-SPV and Kelvin surface voltage measurement. The activation of surface Cu should be configured to enable the UV illumination of the wafer bevel.

In general, the disclosed techniques are sensitive to a range of concentrations of Cu contaminants from about 10⁹ atoms/cm² to about 10¹³ atoms/cm² (e.g., about 10¹² atoms/cm² or less, about 10¹¹ atoms/cm² or less, about 10¹⁰ atoms/cm² or less). The concentration range below about 10¹¹ atoms/cm² is considered, in some respects, the most important for silicon microelectronics.

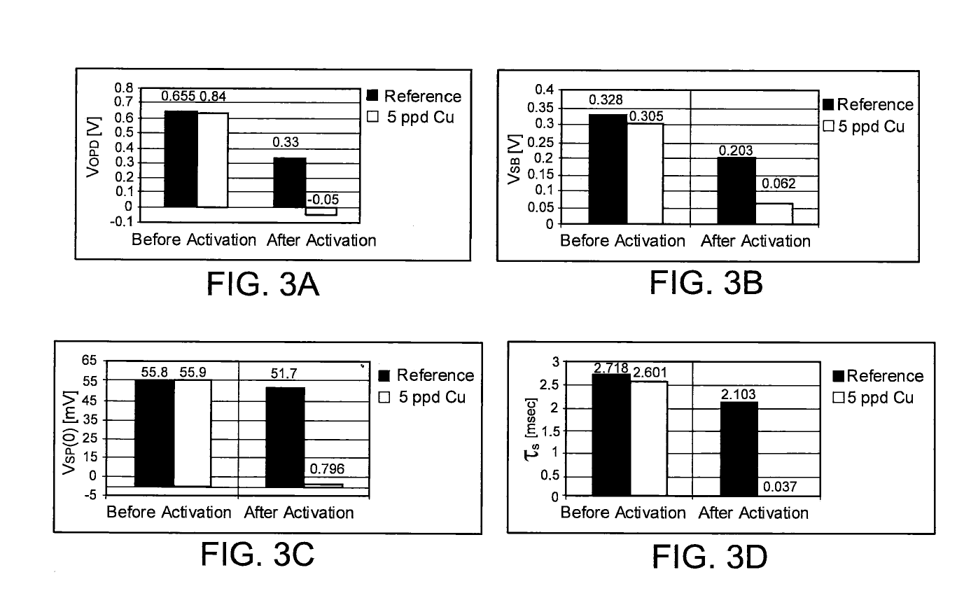

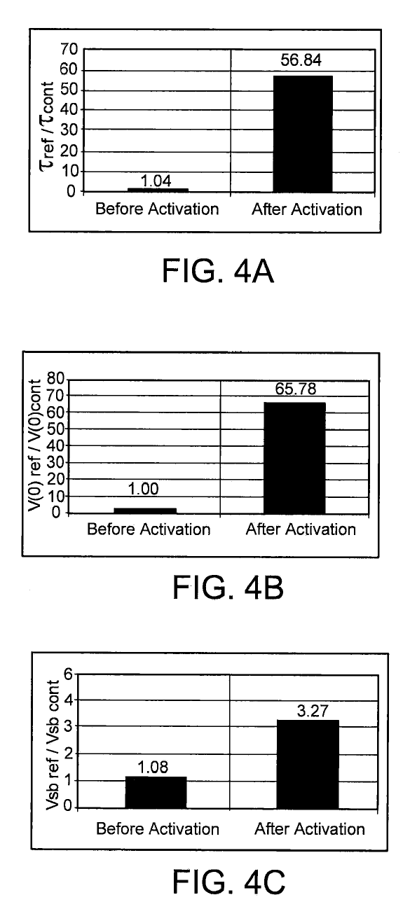

Sensitivity of various electrical parameters to Cu contamination before and after electrical activation of copper is illustrated by the data shown in FIGS. 3A-3D and FIGS. 4A-4C. The results corresponding to “Cu contamination” were obtained for 10Ω cm p-type Si contaminated by 10 min. soaking of the wafer in buffered HF with 5 ppb of Cu. It is believed that this contamination process leaves about 10¹² atoms/cm² of copper on the surface. The reference corresponds to 10 min. soaking of the wafer in buffered HF with no Cu added to the solution. Activation of Cu was performed by UV illumination of the wafer in a commercially available UVO-cleaner® manufactured by Jelight Company Inc. Irvine, Calif.). The activation dose was provided by exposing the wafer for approximately 5 minutes.

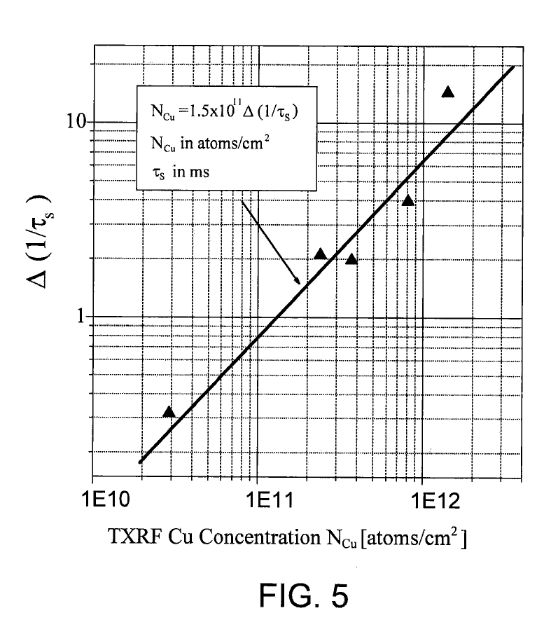

Results from a procedure for monitoring Cu using surface lifetime are shown in FIG. 5 for 10Ω cm p-type Si wafers contaminated with varied contamination level giving surface Cu from about 10¹⁰ atoms/cm² to over 10¹² atoms/cm² as verified by a Total reflection X-ray Fluorescence (TXRF) measurement.

Other embodiments are in the following claims.

What is claimed is:

1. A method, comprising:
exposing a surface of a silicon article to a dose of ultra-violet radiation, wherein the dose is sufficient to electrically activate a substantial amount of copper contaminating the surface of the silicon article relative to the amount of electrically active copper at the surface of the silicon article prior to the exposure;
measuring an electrical parameter of the silicon article before and after the exposure; and
determining information about the copper contamination of the silicon article, based on a measured a change in the measured electrical parameter before and after the exposure.

2. The method of claim 1, wherein the information about the copper contamination is a surface concentration of the copper.

3. The method of claim 1, wherein the electrical parameter is a surface lifetime, τ_{S}.

4. The method of claim 3, wherein the surface lifetime is measured by a surface photovoltage technique.

5. The method of claim 3, wherein the information about the copper contamination is determined from the difference between 1/τ_{S} before and after the exposure.

6. The method of claim 1, wherein the electrical parameter is a low frequency saturation surface photovoltage, V_{SPV0}.

7. The method of claim 6, wherein the information about the copper contamination is determined from the difference between V_{SPV0} before and after the exposure.

8. The method of claim 1, wherein the electrical parameter is a surface recombination.

9. The method of claim 8, wherein the surface recombination is measured by surface photovoltage or by a photoconductive decay method.

10. The method of claim 8, wherein the information about the copper contamination is determined from the change of the value of surface recombination before and after the exposure.

11. The method of claim 1, wherein the electrical parameter is a surface voltage, V_{CPD} measured by a contact potential difference technique.

12. The method of claim 11, wherein the information about the copper contamination is determined from the difference of surface voltage measured before and after the exposure.

13. The method of claim 1, wherein the electrical parameter is a semiconductor surface barrier, V_{SB} measured as the difference of a surface voltage, V_{CPD}, in the dark and under illumination.

14. The method of claim 13, wherein the information about the copper contamination is determined from the difference ΔV_{SB} before and after the exposure.

15. The method of claim 13, wherein the surface barrier V_{SB} is measured by high frequency ac-SPV.

16. The method of claim 1, wherein the silicon article is a silicon wafer.

17. The method of claim 16, wherein the electrical parameter is measured at a bevel of the silicon wafer.

18. The method of claim 16, wherein the electrical parameter is measured at a back surface of the silicon wafer, the back surface being opposite a surface on which integrated circuits are formed.

19. The method of claim 16, wherein the electrical parameter is measured at a front surface of the silicon wafer, the front surface being the surface on which integrated circuits are formed.

20. The method of claim 1, wherein the electrical parameter is measured using a non-contact probe.

21. The method of claim 1, wherein the ultra-violet radiation dose corresponds to a dose provided by a UVO-cleaner® manufactured by Jelight Company Inc., for time of about 30 seconds or more.

22. The method of claim 1, wherein the wafer is at room temperature during the exposure and measurement.

23. The method of claim 1, wherein exposing the silicon article comprises positioning the wafer relative to a source of the ultraviolet radiation using edge grippers.

24. The method of claim 1, further comprising measuring the electrical parameter at different locations on the surface of the silicon article.

25. The method of claim 24, further comprising determining a distribution of copper contamination of the silicon article based on the measurements at the different locations.
